(19) United States
(12) Patent Application Publication
(10) Pub. No.: US 2010/0136895 A1
(43) Pub. Date: Jun. 3, 2010

(54) DATA CENTER AND METHODS FOR COOLING THEREOF

(75) Inventor: Richard O. Sgro, Bristol, CT (US)

Correspondence Address: MICHAUD-Kinney Group LLP, 306 INDUSTRIAL PARK ROAD, SUITE 206, MIDDLETOWN, CT, 06457, US

(73) Assignee: TURNER LOGISTICS, Hawthorne, NY (US)

(21) Appl. No.: 12/543,774

(22) Filed: Aug. 19, 2009

Related U.S. Application Data
(60) Provisional application No. 61/090,057, filed on Aug. 19, 2008.

(51) Int. Cl. H05K 5/02; F28D 15/00; B23P 19/04

(52) U.S. Cl. 454/184; 165/104.34; 29/700

(57) ABSTRACT

Disclosed is a data center and methods for cooling thereof. The data center includes a plurality of data cells. Each data cell included a first heat exchanger, a first set of equipment racks, a second heat exchanger, a second set of equipment racks, and a plurality of fans operable to establish a substantially horizontal and vertical air flow through the heat exchangers and the equipment racks. The data center includes a plurality of mixed air chambers. One air chamber is located between two data cells to form a substantially continuous, closed-loop air flow through the cells and chambers. The air chambers include an outside air intake for drawing ambient air into the closed loop air flow based on a comparison of enthalpy of the closed loop air and the ambient air.

### CROSS-REFERENCE TO RELATED APPLICATIONS

This patent application claims priority benefit under 35 U.S.C. §119(e) of copending, U.S. Provisional Patent Application, Ser. No. 61/090,057, filed Aug. 19, 2008, the disclosure of this U.S. patent application is incorporated by reference herein in its entirety.

### BACKGROUND OF THE INVENTION

1. Field of the Invention

This disclosure relates generally to the field of data centers and more specifically to an improved system and method for providing efficient conditioning of an air flow used for cooling equipment within data centers.

2. Description of Related Art

Generally speaking, data centers are constructed as large brick-and-mortar structures that house data processing, data storage, telecommunications and related electrically powered equipment, hereinafter referred to collectively as computer equipment. The computer equipment is typically mounted into a plurality of racks, which are arranged in parallel rows throughout the data center. With the growth of computer processing in both our personal and professional lives, it is not uncommon for a modern data center to contain hundreds of these racks. Further, with the ever decreasing size of computer equipment and, in particular, computer servers and blade servers, the number of electrical devices mounted in each rack has been increasing, raising concerns about adequately and efficiently cooling the equipment.

Computer equipment in data centers typically generates substantial amounts of heat through its inherent operations and the continuous nature of its use. This heat generation causes increased temperatures within both the computer racks and the data center facilities. The heat collectively generated by very large numbers of densely packed electrical components within a data center is sufficient to cause the computer equipment to shutdown or even fail catastrophically if the heat is improperly handled (e.g., not removed). The computer equipment must therefore be cooled to avoid damage to the equipment, loss of valuable business data, and loss of productivity to a work force relying on use of the computer equipment to perform their jobs. Accordingly, the data centers are typically air conditioned twenty four hours per day, every day of the year.

Traditional brick and mortar data centers are often cooled by computer room air conditioning (“CRAC”) systems that usually include hard piped, immobile units positioned around the periphery of the data center. These CRAC systems typically intake hot air from near the ceiling of the data center, cool it and discharge cooled air under a raised floor on which the equipment racks are installed. In general, CRAC systems intake room temperature air at about 22° C. (72° F.) and discharge cold air at about 12° C. (55° F.). The cold air travels upwardly from vents in the raised floor, through the equipment racks, and toward the ceiling of the data center whereby removing the access heat from the equipment.

The raised-floor, brick-and-mortar data center configuration has several disadvantages. First, the initial construction of such data centers is complicated, expensive and time consuming Second, once constructed, any expansion of data centers' square footage and/or addition of new equipment racks within the existing floor plan are significantly impeded due to the complexity of the data center design and capacity of its CRAC systems housed therein. Furthermore, vertical cooling of computer equipment creates thermal cycle inefficiencies when the heated air is expelled from the equipment racks into the data center, thus raising overall air temperature. The cost of the energy needed to move the airflow required to cool the center, as well as the use of the data center itself as an airflow plenum, contribute to suboptimal cooling.

Recently, computer equipment has been housed in moveable enclosures such as, for example, shipping containers. One or more of the containers are operably coupled to provide new or enhance data center functions. Containers configured in this way are typically referred to as modular or mobile data centers and include their own closed-looped cooling system based on conventional CRAC systems. For example, the modular data centers may employ the above described raised floor delivery of cooling air to cool computer equipment housed therein.

Accordingly, the inventor has discovered that there is a need to improve the cooling systems of both current brick-and-mortar data centers as well as modular data centers to provide an efficient cooling system for computer equipment housed therein.

### SUMMARY OF THE INVENTION

According to aspects disclosed herein, there is provided an improved data center including methods for cooling the data center. In one embodiment, the data center includes a plurality of data cells. Each data cell includes a first heat exchanger followed by a first set of equipment racks; a second heat exchanger followed by a second set of equipment racks; and a plurality of fans operable to establish substantially horizontal and vertical air flow through the heat exchangers and the equipment racks to cool equipment housed in the racks. The data center includes a plurality of mixed air chambers/plenums, at least one mixed air chamber/plenum is located between two of the plurality of data cells to form a substantially continuous, closed-loop air flow through the data cells and the mixed air chambers. The data center may further include a cooling system and operable to provide liquid coolant to the one or more heat exchangers within the plurality of data cells and a power generator operable to provide electric power to the cooling system, the fans, and equipment racks. This configuration provides high performance and cooling efficiency for the data center. In one embodiment, at least one of the mixed air chambers includes an outside air intake for drawing ambient air into the closed loop air flow.

According to one aspect of the invention, when the air flow is passed from a first of data cell to a next data cell through one of the mixed air chambers, the air flow is at least one of passed directly from the first data cell to the next data cell, partially mixed with ambient air drawn in from outside the data center, and the air flow from the first data cell is exhausted and replaced with the ambient air drawn in from outside the data center. In one embodiment, an enthalpy of the air flow passing from the first data cell is compared to an enthalpy of the ambient air such that when the enthalpy of the ambient air is less than the enthalpy of the air flow from the first data cell the ambient air is at least mixed with the air flow passing from the first data cell.

In one embodiment, a method for constructing a data center is disclosed. The method includes receiving a customer order for a data center design. The order may specify the desired power capacity of the data center and other criteria. In response, the method includes providing the customer with one or more data cells, each cell having a predefined power capacity. The data cells include computer equipment racks and associated cooling equipment. The method includes coupling a mixed air chamber to and between the one or more data cells to form a substantially continuous, closed loop air flow through the one or more data cells and the air chambers. In one embodiment, the mixed air chamber includes an outside air intake for drawing ambient air into the closed loop air flow. The data cells may be connected to a liquid cooling system and one or more power generators operable to provide electric power to the cooling system and data cells.

The above described and other features are illustrated by the following figures and detailed description.

### BRIEF DESCRIPTION OF THE DRAWINGS

The accompanying drawings, which are incorporated into and constitute a part of this disclosure, illustrate one or more example of embodiments and, together with the description of example embodiments, serve to explain the principles and implementations of the embodiments.

FIG. 1 is a block diagram of a data center including a plurality of data cells, according to one embodiment;

FIG. 2 is a block diagram of a data center according to another example embodiment;

FIG. 3 is a block diagram of a data center according to yet another example embodiment;

FIG. 4 is a schematic diagram of a data cell according to one embodiment;

FIG. 5 is a schematic diagram of a data center including a number of the data cells of FIG. 4, according to one embodiment;

FIG. 6 is a data center heat transfer diagram according to one example embodiment;

FIG. 7 is a partially cross-sectional side view of the data center of FIG. 5 according to one embodiment; and

FIGS. 7A and 7B are partial detailed views of components of the data center of FIG. 7 illustrating rooftop and wall mounted ventilation.

### DETAILED DESCRIPTION OF PREFERRED EMBODIMENTS

The following description is illustrative only and is not intended to be in any way limiting. Example embodiments are described herein in the context of a mobile data center environment. Those of ordinary skill in the art will realize that the data center construction and cooling principles disclosed herein may be applied equally to brick-and-mortar data centers and other data processing, data storage and/or networking facilities. Other embodiments will readily suggest themselves to such skilled persons having the benefit of this disclosure. Reference will now be made in detail to implementations of the example embodiments as illustrated in the accompanying drawings. The same reference indicators are used to the extent possible throughout the drawings and the following description to refer to the same or like items.

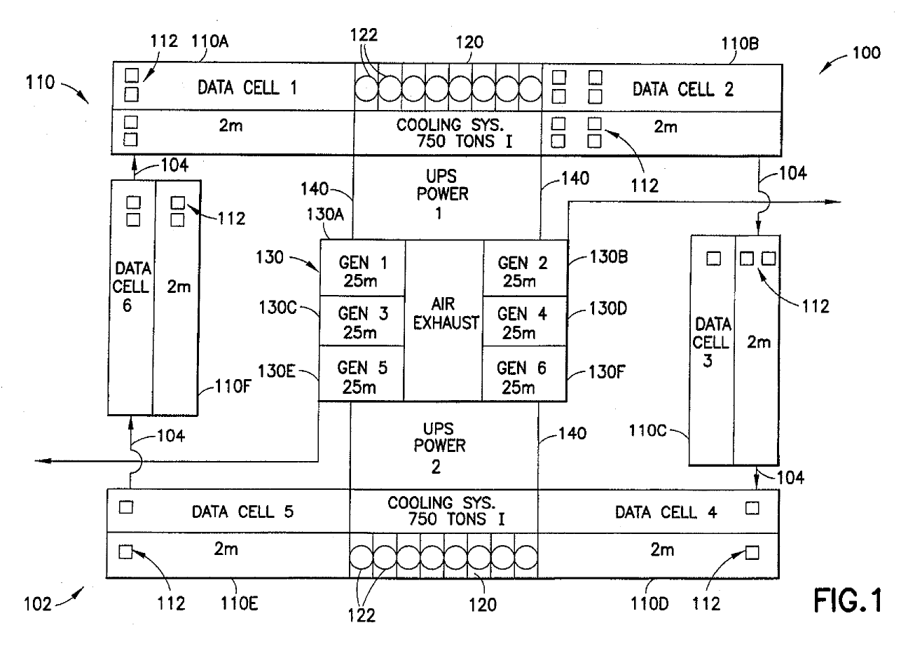

Turning now to FIG. 1, depicted is one embodiment of a data center facility 100 constructed in accordance with principles set forth herein. The data center 100 includes a plurality of structures at a data center site 102 that may be housed in a building or in the open air on a concrete slab. The plurality of structures of the data center 100 include a plurality of data cells 110 (e.g., data cells 110A-110F shown), which house data processing, data storage, networking equipment and like computer equipment shown generally at 112, as well as various cooling systems 120 (e.g., cooling systems 120A and 120B shown) including cooling components shown generally at 122 for cooling of computer equipment housed in the data cells 110. In one embodiment, the data cells 110 may be preassembled and shipped to the data center site 102 in a standard ISO shipping container. To that end, the dimensions of each data cell 110 may correspond to the container dimensions of, for example, having lengths of 20 feet (6.1 m), 40 feet (12.2 m), 45 feet (13.7 m), 48 feet (14.6 m), and 53 feet (16.2 m), and widths of, for example, 8 feet (2.4 m), 12 feet (3.7 m), 16 feet (4.9 m), 18 feet (5.5 m), and 24 feet (7.3 m), and heights of, for example, 8 feet (2.4 m) and 12 feet (3.7 m). In one embodiment, the data cell is 18 feet (5.5 m) wide, 12 feet (3.7 m) high, and 53 feet (16.2 m) long. Alternatively, the dimensions of a data cell may be customized to conform to customer-specified parameters of other criteria known in the art.

As shown in FIG. 1, the plurality of data cells 110 (e.g., data centers 110A-110F) are arranged along a perimeter of the data center site 102 to provide the data center 100. Power generators 130 (e.g., power generators 130A-130F shown) and cooling equipment are located in proximity to the data cells 110A-110F. As shown in FIG. 1, the data center 100 includes the one or more cooling units 120 (e.g., cooling units 120A and 120B) that monitor and condition a cooling air flow by maintaining acceptable temperature, air distribution through the data cells 110 and humidity level within the data cells 110. The plurality of power generators 130 (e.g., six power generators 130A-130F) include, for example, fuel cells, diesel, solar or other types of generators, which provide electric power to the data cells 110 and cooling units 120. The data center 100 may also include a plurality of uninterrupted power supplies (“UPS”) 140 (e.g., UPS 140A and 140B shown), which provide the back up electric power for the data center 100. In various embodiments, the data center 100 may also include other redundant data storage or backup components, redundant data communications connections, environmental controls such as, for example, fire suppression, and various security devices known to those of ordinary skill in the art.

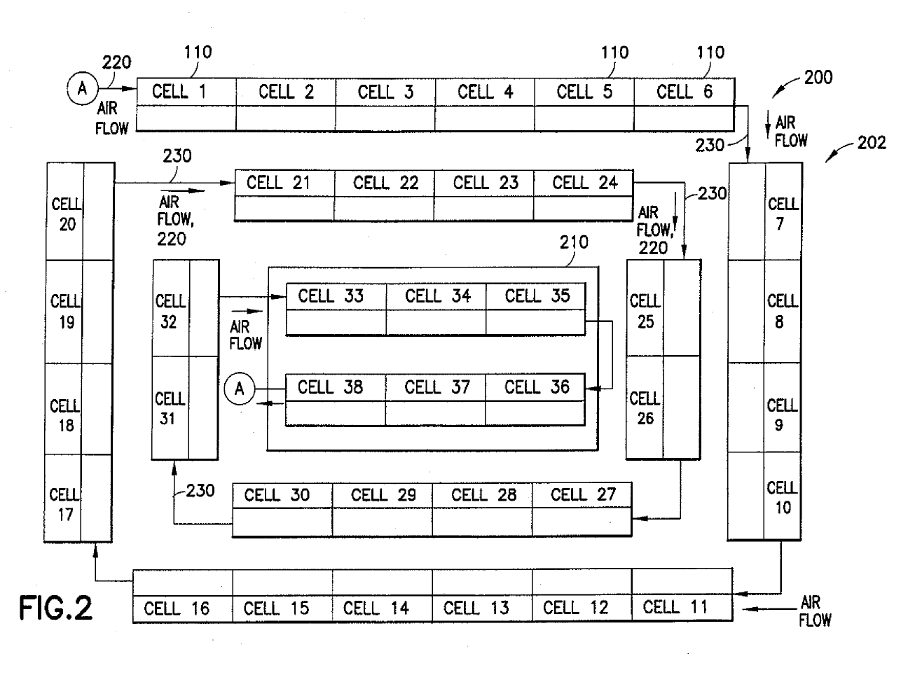

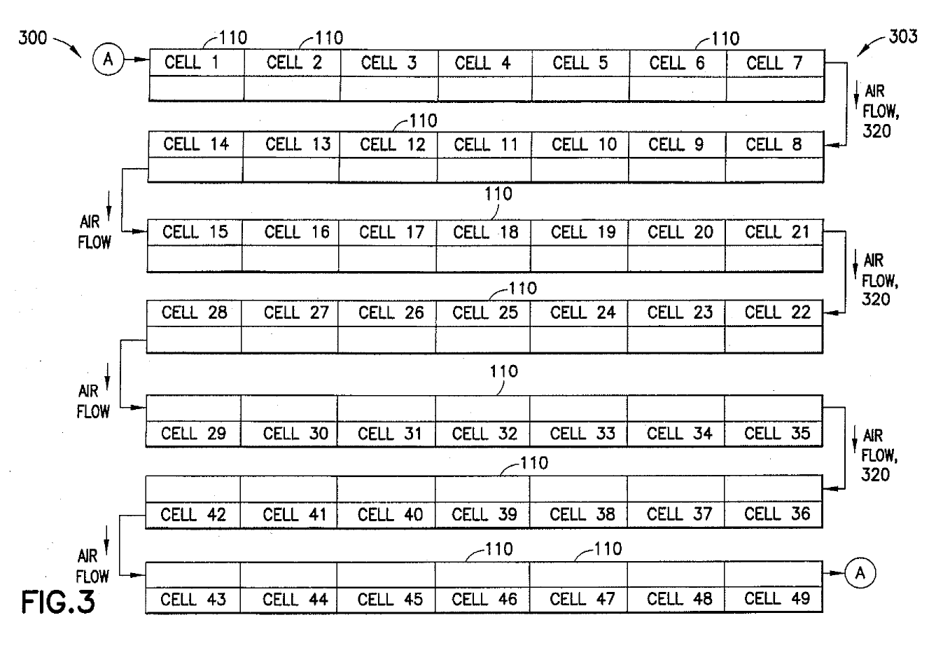

It should be appreciated that FIG. 1 depicts only one exemplary configuration of data cells 110 forming the data center 100, in accordance with the present invention. Accordingly, those of ordinary skill in the art will appreciate that there are other data cell and data center configurations with different dimensions, computing capacities, power densities, numbers of data processing, cooling and power generation components, and other factors which are within the scope of the present disclosure. For example, FIG. 2 depicts another data center configuration 200 in which a plurality of rows of the data cells 110 are arranged in concentric rectangles around a centrally located core 210 including the power generation 130 and cooling 120 systems. As shown in FIG. 2, the data center 200 includes thirty-eight (38) data cells 110, each having for example, about 2 MW power density, placed on data center site 202 such as, for example, a rectangle concrete slab of 385×320 square feet and having a continuous flow of cooling air 220 cycling there through via conduits 230. Yet in another example embodiment depicted in FIG. 3, a data center 300 is configured to include forty-nine (49) data cells 110 placed in parallel rows on a data center site 303 such as, for example, a rectangle slab of 835×330 square feet and passing a continuous flow of cooling air 320 there through.

With reference again to FIG. 1, the data center 100 includes one or more cooling systems 120 (e.g., cooling systems 120A and 120B), which monitor and maintain the air temperature, air distribution and humidity within the data cells 110 of the data center 100 in accordance with the present invention. In one embodiment, the components 122 of the cooling systems 120 include a liquid-to-air heat exchange system that circulates a flow of cooling air through the data cells 110 directly and/or through distribution conduits 104 between the data cells 110 and, as described below, periodically transfers the heat generated by computer equipment 112 to the ambient and/or mixes ambient air from outside the data center 100 with the flow of air through the data cells 110. The cooling systems 120 include one or more units having, for example, about seven hundred fifty (750) tons of capacity for cooling one or more data cells 110. Generally, the cooling systems 120 monitor and maintain the temperature in each of the data cells in a range of about 15-32° C. (about 60-90° F.) and, preferably, about 20-22° C. (about 68-72° F.), and a relative humidity in a range of between about twenty to eighty percent (20% to 80%) and, preferably, about thirty-five to sixty-five percent (35% to 65%). As described below, other temperature and humidity ranges may be used when cooling the data cells 110.

In one embodiment, the components 122 of the cooling system 120 may include a refrigeration unit, a coolant pump and a plurality of heat exchangers located within each of the one or more data cells 110. The refrigeration unit cools a liquid coolant to a predetermined temperature of, for example, about 12° C. (55° F.). The coolant may include various organic solutions such as, for example, water, ammonia, propylene glycol, ethanol, isopropanol (IPA) and the like. Alternatively, the fluid within the cooling system 120 may be a pumped refrigerant. Generally, the fluid used in the cooling system 120 exhibits a low freezing temperature and has anti-corrosive characteristics. The coolant pump may be any conventional pump, including, but not limited to, an electro-osmotic pump and a mechanical pump. The heat exchangers may be located within the data cells 110 to remove the heat output from the computer equipment 112 housed therein, as will be described below.

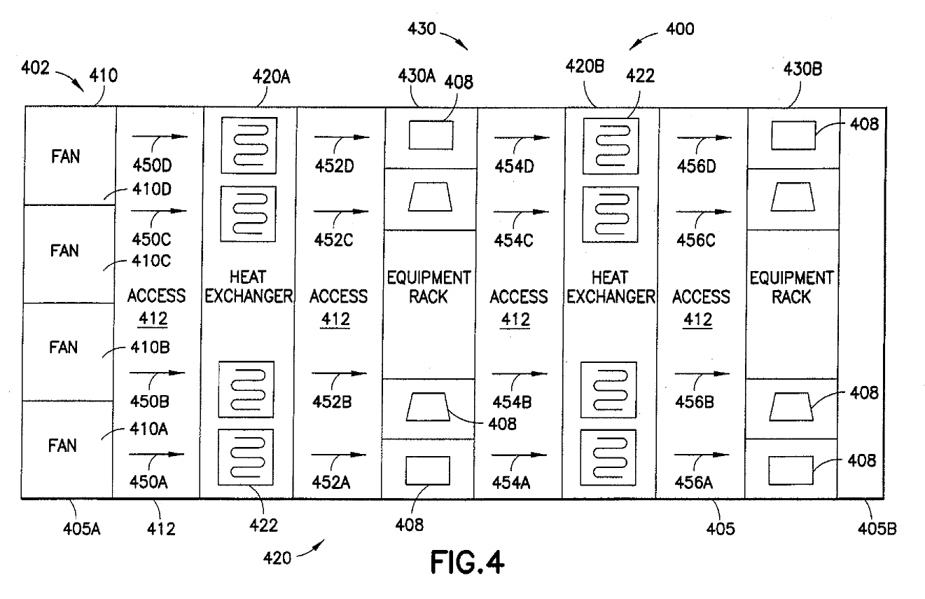

FIG. 4 depicts one embodiment of a data cell, shown generally at 400. The data cell 400 includes an open or enclosed chassis 405 that houses the computer equipment 112 and cooling equipment 402. In one embodiment, the computer equipment 112 includes a plurality of blade or rack servers 408 such as, for example, web servers, application servers, database servers, network routers or other types of data processing, data storage and/or networking equipment. Some examples of server systems include Dell® PowerEdge rack or blade servers, Intel® Server Compute Blades, Sun® Blade servers or others. The computer equipment 112 (e.g., the servers 408) are housed within the chassis 405 in one or more upright equipment racks 430 (e.g., two racks 430A and 430B shown). Access is provided to the racks 430 in one or more access sections 412. The racks 430 may include distribution connections for providing power and communication connectivity to and between the equipment 410 housed therein. In one embodiment, equipment racks 430 may include a Dell® PowerEdge Rack enclosure, INTEL® Blade server Chassis, SUN® Blade Chassis or other types of server chassis and racks.

In one embodiment, the computer cooling equipment 402 includes one or more fans 410 (e.g., four fans 410A-410D shown spanning a width of the chassis 405) and one or more heat exchangers 420 (e.g., two heat exchangers 420A and 420B shown). Exemplary fans 410 include an array of high-efficiency airfoil plenum fan system sold under the brand name FANWALL® system by HUNTAIR, Inc., Tualatin, Oregon (USA). The Fanwall system provides 75,000 CFM. Exemplary heat exchangers 420 include cooling coils provided by, for example, Ventrol Air Handling Systems Inc., Anjou (Québec). In one embodiment, the fans 410 are arranged at a first end 405A of the chassis 405 in a plurality of vertically and horizontal rows and columns to draw a flow of air from outside the chassis 405 into the data cell 400 and to direct the air toward the heat exchangers 420 and equipment racks 430 (e.g., two equipment racks 430A and 430B shown). The power and arrangement of the fans 410 are sufficiently to establish a substantially horizontal and vertical air flow (described below) from the first end 405A to a second end 405B of the chassis 405 over a height and width of the data cell 400. In one embodiment, the fans 410 provide a substantially free flow of air over substantially all of the height and width of the data cell 400. In one embodiment, the air flow is in a velocity range of between about two hundred fifty to about six hundred feet per minute (250 to 600 fpm) and, preferably, about 450 to 550 fpm. Although it is within the scope of the present invention to permit a free flow of air at different velocity ranges (greater or lesser velocity) as an application dictates.

In one embodiment, the heat exchangers 420A and 420B include one or more coolant coils 422, which circulate liquid coolant provided to the data cell 400 by the external cooling system 120. As shown in FIG. 4, the heat exchanger 420A receives the air flow 450A-450D from the fans 410A-410D, cools the air and provides the cooled air flow 452A-452D in the direction of the computer rack 430A. As the cooled air flows through the computer rack 430A heat generated by the computer equipment 112 (e.g., the servers 408) housed in the rack 430A is removed to cool the computer equipment 112. An air flow 454A-454D warmed by the rack 430A flows to the heat exchanger 420B and is passed over the coolant coils 422 to again cool the air flow. The cooled air flow 456A-456D passes from the heat exchanger 420B to the computer rack 430B where the air flow 456A-456D removes heat generated by the computer equipment 112 stored in the rack 430B.

The inventor has recognized that the heat generated by the computer equipment 112 in the racks 430 varies from application to application and over time. For example, applications vary in that the computer equipment 112 disposed in the racks 430 may include a mix of differing components that have different power and cooling requirements. The mix and different power and cooling requirements need not merely be a function of the number (density) and differing types of equipment, for example, servers versus data storage devices housed in a rack, as variations may be seen in a same type of equipment produced by different manufacturers. In one embodiment, each of the racks 430 includes six (6) servers 408, each server 408 providing about forty kilowatts (40 KW) of processing power, for an about two hundred forty kilowatts (240 KW) of processing power per rack and an about four hundred eighty kilowatts (480 KW) of processing power per data cell 110 (e.g., cells having two racks 430A and 430B). Moreover, this arrangement provides a free air flow area through each server of about forty percent (40%) of the face area.

Additionally, periods of time may influence heat generation. For example, the computer equipment 112 may experience differing periods of operational load such that a greater degree of heat is generated at a point in time that the equipment is performing more tasks versus when the equipment is idle. These periods of various loads result in hot spot areas within the air flow described above, e g , immediately before, during and after impact with a high load piece of equipment (e.g., within the flow from 452A to 454A). The inventor has recognized that blending the air flow prior to its entry into a data cell (e.g., at mixed air chambers/plenums described below) and/or in proximity to the hot spot areas permits, for example, establishing a higher velocity flow over or more efficient cooling flow about (e.g., circular flow about) the heat producing device.

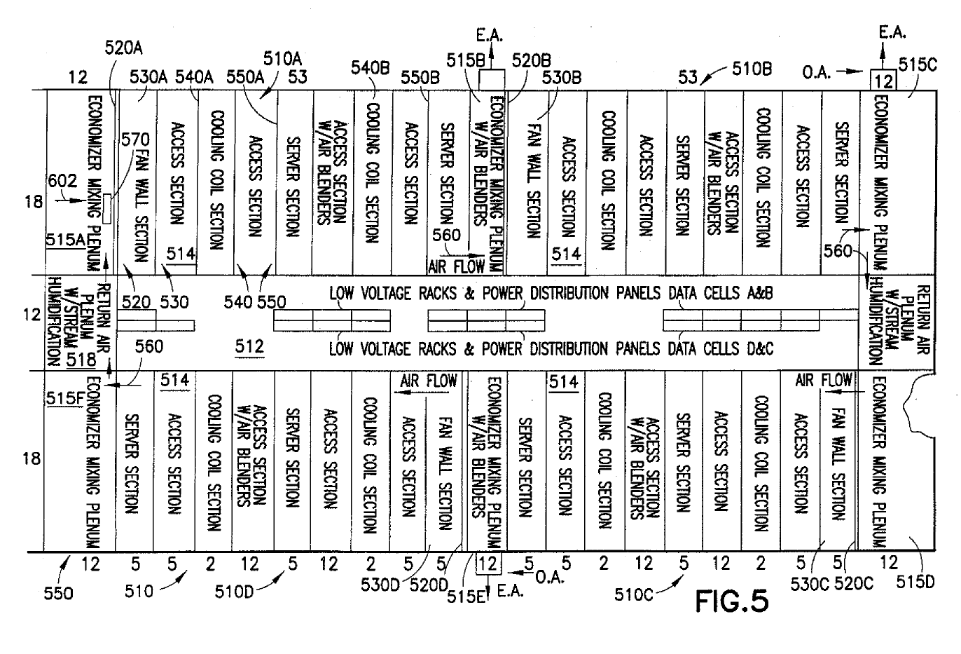

FIG. 5 depicts one embodiment of a data center 500 comprised of a plurality of data cells 510 (e.g., four data cells 510A-510D shown) connected via one or more mixed air chambers/economizer mixing plenums 515 (e.g., six mixed chambers/plenums 515A-515F shown) having a continuous air tunnel 560 (e.g., air stream) flowing there through for cooling computer equipment 112 contained therein. The data cells 510 are substantially similar to the data cell 400 of FIG. 4. In one embodiment, the mixed air chambers/plenums 515 include measuring and control equipment 570 such as a controller 572, sensors 574 and an air blender or mixer 576. In one embodiment the air blender 576 includes, for example, a static air blending device sold under the brand name Series IV Air Blender by Blender Products, Inc., Denver, Colorado (USA). As shown in FIG. 5, the air blender 576 is disposed in the mixed air chamber 515 upstream of the air filter 520 and receives the continuous air flow 560 through the closed loop system of data cells 510 (e.g., the return, cycling air) and outside air 602 received into the mixed air chamber. The blender 576 is used to reduce air stratification seen when varying air temperature streams are merged. As is generally known, air stratification is the tendency of two or more airstreams to remain separated due to, for example, one or more of a temperature difference between the two air streams (as measured by temperature sensors), or the inherent momentum/velocity of each stream (as measured by velocity sensors). In one embodiment, air stratification is also minimized by employing mixed air chambers having sufficient distance between the outside air intake and the return air path to allow the two air streams to mix. Accordingly, it is within the scope of the invention to utilize one or both solutions of mechanically blending the air flow with the blenders 576 and/or providing mixed air chambers/plenums of sufficient length to allow blending of the air streams as they traverse the chamber/plenum 515. As shown in FIG. 5, in one embodiment, one or more of the air chambers 515 are coupled via a humidity control section 518. While shown as a separate area in FIG. 5, it should be appreciated that the humidity control section 518 may be merged within the mixed air chambers 515. In the humidity control section 518, the sensors 574 include a humidity sensor that monitors the relative humidity of the closed loop air flow and conditions the stream by, for example, adding moisture via a steam inlet or adjusting the relative humidity of the air flow by mixing the closed loop flow with outside air. It should be appreciated that the humidity section 518 may include one or more of the aforementioned humidity, temperature and velocity sensors. The inventor has also recognized that humidity may be of particular concern at certain time periods such as, for example, at initial start up. In one embodiment, heaters may be added to the data center 500, e.g., in one or more of the mixed air chambers/plenums 515 to dry out relatively excessive moisture/humidity in the air flow. Once humidity is stabilized, the heaters may be powered down or removed from the data center 500.

In one embodiment, each of the data cells 510 includes, in the direction of air flow, a filter module 520 (e.g., four filter modules 520A-520D shown), and a plurality of fans 530 (e.g., four fan walls 530A-530D shown). Each of data cells 510A-510D also includes an alternating arrangement of heat exchanger/cooling coils 540 (e.g., cooling coils 540A and 540B shown) and computer equipment racks 550 (e.g., racks 550A and 550B shown). It should be appreciated that while an arrangement of two cooling coil-equipment racks is shown, it is within the scope of the present invention to deploy more arrangements per data cell or to vary the number of arrangements in differing cells. Moreover, it is also within the scope of the present invention to pass air from one coil 540 through two or more racks 550. As such, the alternating arrangement of cooling coil-equipment racks need not be a one-to-one repeated pattern, as two or more equipment racks may be disposed between each cooling coil.

As shown in FIG. 5, the air stream 560 (e.g., the air flow tunnel) is received at the mixed air chamber 515A and enters the data cell 510A by passing through the filter module 520A and the fan wall 530A. The fans 530A pass the air stream 560 through the cooling coil 540A where the air may or may not be cooled (depending on the incoming temperature of the air stream 560). Once through the cooling coil 540A, the air flows through the rack 550A resulting in a rise in temperature (temperature delta) proportional to the heat output from the computer equipment 122 housed in the rack 550A. In one embodiment, a temperature delta of about 9.4° C. (15° F.) is typical in an air flow of about 72,000 CFM. The air stream then passes from the rack 550A to the cooling coil 540B with or without being cooled depending on the temperature of the air and then passes through the rack 550B resulting again in a rise in temperature proportional to the heat output from the computer equipment 122 housed in the rack 550B. The air stream 560 exits the first data cell 510A and enters the mixed air chamber 515B. As shown in FIG. 5, the data center 500 may include an optional maintenance aisle 512 extending along the entire length of the data center between data cells 510A, 510B, and 510C, 510D and access sections 514 to allow for servicing of computer equipment housed in the data cells. As shown in FIG. 5, each data cell is separated from its neighbor by one of the mixed air chambers 515. As described herein, the chambers 515 are outside air intake/exhaust areas and may include a rooftop air intake vents as known to those of ordinary skill in the art. The air intake vents may be periodically actuated (e.g., opened and closed by the controller 572) to draw fresh ambient air into the interior of the data center 500. That is, and as is noted above, the air stream 560 is passed in a continuous manner through data cells 510A-510D and intervening mixed air chambers 515A-515F.

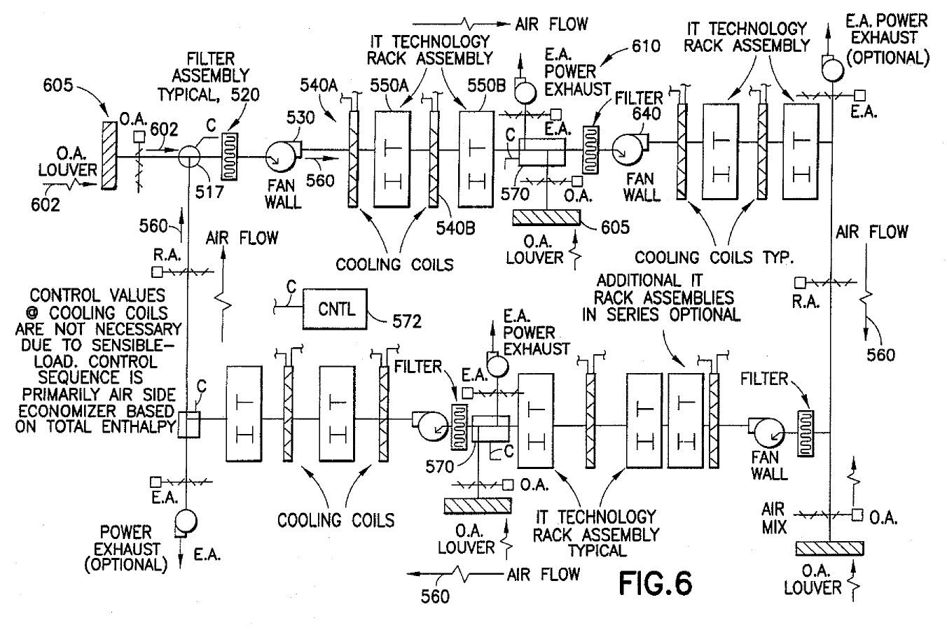

In one embodiment, the continuous flow employs a free cooling concept where air passing from one data cell to a next data cell may be passed directly between cells, may be supplemented and partially mixed with ambient air drawn in from outside the data center 500, or the air stream from one cell may be completely exhausted and replaced by new ambient air drawn from outside the data center 500 and provided to the next data cell 510. This mix of air is employed by the controller 572 when the ambient air is within a predetermined threshold temperature such that it is more efficient to drawn in completely or partially new ambient air rather than condition (e.g., cool) the air stream 560 as it passes from one data cell to a next data cell. Efficiency favors drawing new ambient air when the enthalpy of the ambient air (e.g., air outside the data center 500) is less than the enthalpy of the air stream 560 circulating within the data cells as conditioning (e.g., cooling, humidifying/dehumidifying) the outside air is more energy efficient than conditioning the circulating air stream 560. As can be appreciated, employing the above described free cooling concept can increase efficiency of the cooling process and reduce energy costs. However, it should also be appreciated that the climate in which the data center 500 is situated (e.g., various weather conditions) can influence the balance of how much, if any, ambient air can be used within the air flow 560. FIG. 6 illustrates the control flow process by means of a heat transfer diagram 600.

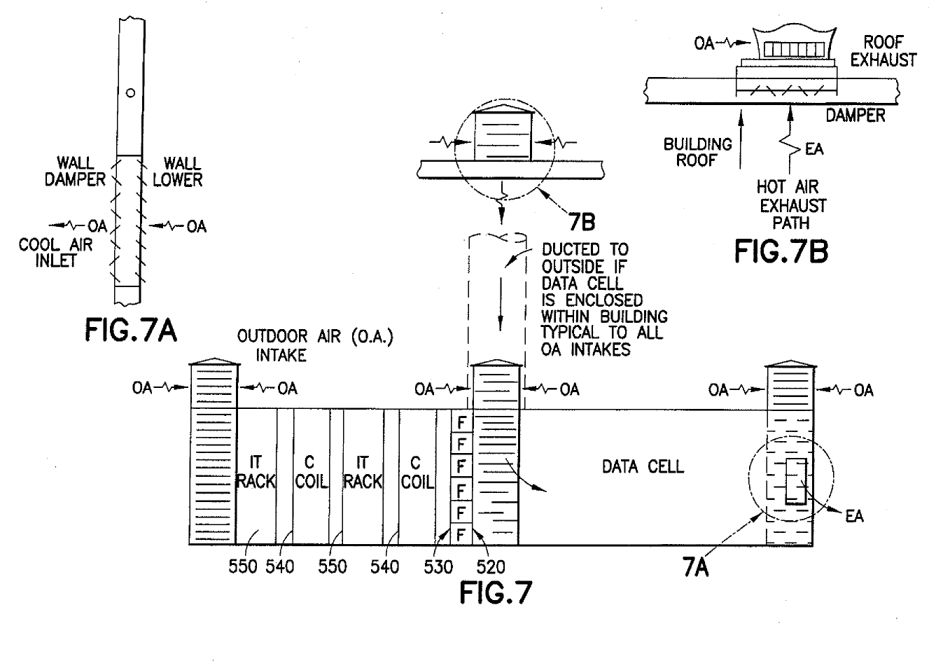

As shown in FIGS. 5 and 6, ambient air 602 may be drawn into the air stream 560 circulating through the data center 500 through one or more air vents 605 such as, for example, a rooftop 710 and/or a side wall 720 air vent or louvers (FIGS. 7, 7A and 7B) in accordance with predetermined temperature, humidity and velocity characteristics measured, monitored and maintained within the flow 560 by the measuring and control equipment 570 (e.g., the controller 572 actuating equipment (vents, blenders) via control signals C. As described above, it is within the scope of the present invention to employ measuring and control equipment 570 such as the air blender to mix the air stream 560 circulating within the closed-loop arrangement of data cells (e.g., return air) with the ambient air 602 drawn in from outside the data center 500. The blended air stream 560/ambient air 602 is drawn into the data cell through the filter module 520 by the fans 530. In one embodiment, the predetermined air flow characteristics (temperature, humidity and velocity) into a data cell are balanced by the measuring and control equipment 570 in consideration of the heat load of the components operating within the data cell. The air is cooled by the first set of heat exchangers 540A and passed through the first set of equipment racks 550A, thereby cooling equipment housed therein. The air is then cooled by the second set of heat exchangers MOB and passed through the second set of equipment racks 550B. The air flow 560 may then be exhausted through the power exhaust 610 or may be drawn into the adjacent data cell 510B by its fans 530B, whereby the cooling process is repeated. The air flow 560 may then be directed into the data cell 510C and then into data cell 510D through the corresponding mixed air chambers 515C, 515D and 515E. At that point once, all data cells have been cooled and the air may be continuously circulated from one data cell to another in a closed loop until temperature or humidity conditions need to be adjusted.

The disclosed data center configurations and methods for cooling thereof have numerous advantages. For example, the above described system configuration increase the cooling process efficiency, IT processor efficiency and overall IT industries energy consumption requirements within the data center space. Efficiency increases are as far stretching as the building main cooling source compressor coefficient of performance (COP), electrical substation and electrical distribution system capacity requirements, as well as a reduction (lower CFM) in the quantity of computer room air conditioning/air handling equipment.

In contrast to the raised-floor data centers, the disclosed configuration provides improved scalability in cases where computing capacity of the data center needs to be increased. The configuration can be easily expanded with additional data cells without significant modifications the existing data center infrastructure. Additional benefits include a greater level of processing watts per foot square without the additional cost of mechanical/electrical infrastructure equipment and/or build out square footage of raised floor space. Lower energy consumption of the data center itself when related to producing the same IT processing performance of other data centers, as well as other processing and cooling efficiencies.

The diagrams in FIGS. 1-7 have been simplified to include primarily elements of various embodiments of the data center, its various components and methods for cooling thereof. Those of ordinary skill in the art will readily identify other elements that might also be included as desired or required. Other means of implementing the data center cooling system are also known to those of skill in the art and are not intended to be excluded. For example, the data center configurations 200 and 300 of FIGS. 2 and 3 should be understood as including mixed air chambers/plenums such that air flows directly from one cell to a next cell and/or flows through a mixed air chamber/plenum between two data cells and/or flows through a mixed air chamber/plenum between more than two data cells. While embodiments and applications have been shown and described, it would be apparent to those skilled in the art having the benefit of this disclosure that many more modifications than mentioned above are possible without departing from the inventive concepts disclosed herein. The invention, therefore, is not to be restricted except in the spirit of the appended claims.

What is claimed is:

1. A data center comprising:
a plurality of data cells, each data cell including:
a first heat exchanger thermally coupled to a first set of equipment racks;
a second heat exchanger thermally coupled to a second set of equipment racks,
wherein the first and the second heat exchangers are coupled to an external cooling system to receive liquid coolant therefrom; and
a plurality of fans operable to establish substantially horizontal and vertical air flow through the first and second heat exchangers and the first and second sets of equipment racks;
a plurality of mixed air chambers, at least one of the mixed air chambers is disposed between two of the plurality of data cells to form a substantially continuous, closed-loop air flow through the plurality of data cells and the plurality of air chambers; and
a power generator operable to provide electric power to the cooling system and the plurality of data cells.

2. The data center of claim 1, wherein each of the first and the second set of equipment racks are configured to house at least one of data processing, data storage and telecommunications networking equipment.

3. The data center of claim 1, wherein at least one of the mixed air chambers includes an outside air intake for drawing ambient air into the closed loop air flow.

4. The data center of claim 3, wherein the air flow passing from a first of data cell to a next data cell through one of the mixed air chambers is at least one of passed directly from the first data cell to the next data cell, partially mixed with ambient air drawn in from outside the data center, and the air flow from the first data cell is exhausted and replaced with the ambient air drawn in from outside the data center.

5. The data center of claim 4, wherein an enthalpy of the air flow passing from the first data cell is compared to an enthalpy of the ambient air such that when the enthalpy of the ambient air is less than the enthalpy of the air flow from the first data cell the ambient air is at least mixed with the air flow passing from the first data cell.

6. The data center of claim 1, wherein at least one of the plurality of the data cell is manufacture off site and assembled at a data center site.

7. The data center of claim 5, wherein the data cell is shipped to the data center site as a modular data cell disposed within a shipping container.

8. A method for constructing a data center, the method comprising:
receiving a customer order for a data center design, the order specifying at least the power capacity of the data center;
providing one or more data cells each having a predefined power capacity and including computer equipment racks and associated cooling equipment;
coupling a mixed air chamber to and between the one or more data cells to form a substantially continuous, closed-loop air flow through the one or more data cells and the air chamber, the mixed air chamber including an outside air intake for drawing ambient air into the closed loop air flow;
connecting a liquid cooling system to the data cells; and
connecting a power generator operable to provide electric power to the cooling system and the data cells.

9. The method of claim 8, further including:
comparing an enthalpy of the air flow passing from a first data cell to an enthalpy of the ambient air; and
when the enthalpy of the ambient air is less than the enthalpy of the air flow from the first data cell, mixing the ambient air with the air flow passing from the first data cell to a second data cell.

10. The method of claim 9, wherein when the enthalpy of the ambient air is significantly less than the enthalpy of the air flow from the first data cell, exhausting the air flow from the first data cell and replacing the air flow with the ambient air drawn in from outside the data center.
